(19) United States
(12) Patent Application Publication
(10) Pub. No.: US 2023/0303416 A1
(43) Pub. Date: Sep. 28, 2023

(54) ULTRAPURE WATER SUPPY APPARATUS, SUBSTRATE PROCESSING SYSTEM INCLUDING THE SAME, AND SUBSTRATE PROCESSING METHOD USING THE SAME

(71) Applicant: Samsung Electronics Co., Ltd., Suwon-si (KR)

(72) Inventors: Jongha Yun, Suwon-si (KR); Gwangwon Son, Suwon-si (KR); Jieun Jang, Suwon-si (KR); Wuyoung Choi, Suwon-si (KR); Eunhye Park, Suwon-si (KR)

(21) Appl. No.: 18/065,857

(22) Filed: Dec. 14, 2022

(30) Foreign Application Priority Data
Mar. 22, 2022 (KR) 10-2022-0035216

(51) Int. Cl. B08B 3/14; C02F 9/00; B01D 63/02; H01L 21/67; B01D 15/36; B01D 61/02; B01D 61/08; B08B 3/02; B08B 13/00; H01L 21/306

(52) U.S. Cl. CPC C02F 9/00; B01D 15/361; B01D 61/025; B01D 61/08; B01D 63/02; B08B 3/022; B08B 3/14; B08B 13/00; H01L 21/30604; H01L 21/6708; C02F 2103/04

(57) ABSTRACT

An ultrapure water supply apparatus includes a first filtering device, a second filtering device, a first tank between the first and second filtering devices, a third filtering device, a second tank between the second and third filtering devices, a fourth filtering device, a third tank between the third and fourth filtering devices, and a gas supply device connected to each of the first to third tanks and configured to supply an inert gas. Each of the first to third tanks includes a tank body and a breather valve coupled to the tank body and connected to a storage space in the tank body. Each of the first to fourth filtering devices includes at least one selected from an activated carbon filter device, an ion exchange resin device, a reverse osmosis membrane device, and a hollow fiber membrane device.

### CROSS-REFERENCE TO RELATED APPLICATION

This U.S. nonprovisional application claims priority under 35 U.S.C § 119 to Korean Patent Application No. 10-2022-0035216, filed on Mar. 22, 2022 in the Korean Intellectual Property Office, the disclosure of which is hereby incorporated by reference in its entirety.

### BACKGROUND

The present inventive concepts relate to an ultrapure water supply apparatus, a substrate processing system including the same, and a substrate processing method using the same, and more particularly, to an ultrapure water supply apparatus capable of preventing contamination of ultrapure water during its production and/or supply, and a substrate processing system including the same, and a substrate processing method using the same.

A semiconductor device may be fabricated by a series of processes. For example, the semiconductor device may be manufactured through a photolithography process, an etching process, a deposition process, a polishing process, and a cleaning process on a silicon wafer. Such processes may use ultrapure water (UPW). The ultrapure water may indicate water with low electrical conductivity and less impurity. The ultrapure water may be produced through a separate procedure. It may be required that the produced ultrapure water be supplied at or above a certain flow rate to a substrate processing apparatus.

### SUMMARY

Some embodiments of the present inventive concepts provide an ultrapure water supply apparatus capable of using an inert gas to protect ultrapure water, and a substrate processing system including the same, and a substrate processing method using the same.

Some embodiments of the present inventive concepts provide an ultrapure water supply apparatus capable of protecting a tank in which ultrapure water is stored, and a substrate processing system including the same, and a substrate processing method using the same.

Some embodiments of the present inventive concepts provide an ultrapure water supply apparatus capable of continuously supplying an inert gas, and a substrate processing system including the same, and a substrate processing method using the same.

Objects of the present inventive concepts are not limited to those mentioned above, and other objects which have not been mentioned above will be clearly understood to those skilled in the art from the following description.

According to some embodiments of the present inventive concepts, an ultrapure water supply apparatus may include: a first filtering device; a second filtering device connected to the first filtering device; a first tank between the first filtering device and the second filtering device; a third filtering device connected to the second filtering device; a second tank between the second filtering device and the third filtering device; a fourth filtering device connected to the third filtering device; a third tank between the third filtering device and the fourth filtering device; and a gas supply device connected to each of the first tank, the second tank, and the third tank, the gas supply device configured to supply an inert gas. Each of the first, second, and third tanks may include: a tank body; and a breather valve coupled to the tank body and connected to a storage space in the tank body. Each of the first, second, third, and fourth filtering devices may include at least one selected from an activated carbon filter device, an ion exchange resin device, a reverse osmosis membrane device, and a hollow fiber membrane device.

According to some embodiments of the present inventive concepts, a substrate processing system may include: a semiconductor fabrication apparatus; and an ultrapure water supply apparatus configured to produce ultrapure water and supply the semiconductor fabrication apparatus with the ultrapure water. The ultrapure water supply apparatus may include: a first filtering device; a second filtering device connected to the first filtering device; a first tank between the first filtering device and the second filtering device; and a gas supply device configured to supply the first tank with an inert gas. The first tank may include: a tank body; and a breather valve coupled to the tank body and connected to a storage space in the tank body. The gas supply device may include: a gas storage tank that stores the inert gas; a gas supply pipe that connects the gas storage tank and the tank body; a filter on the gas supply pipe; and a pressure control valve on the gas supply pipe.

According to some embodiments of the present inventive concepts, a substrate processing method may include: using an ultrapure water supply apparatus to produce ultrapure water; supplying the ultrapure water from the ultrapure water supply apparatus to a semiconductor fabrication apparatus; and using the ultrapure water to treat a substrate in the semiconductor fabrication apparatus. The step of producing the ultrapure water may include: passing a fluid sequentially through a plurality of filtering devices to filter the fluid; and storing the fluid in a tank between the plurality of filtering devices. The step of storing the fluid in the tank may include: supplying an inert gas to the tank in which the fluid is stored; and discharging the inert gas from the tank.

Details of other example embodiments are included in the description and drawings.

### BRIEF DESCRIPTION OF THE DRAWINGS

FIG. 1 illustrates a schematic diagram showing a substrate processing system according to some embodiments of the present inventive concepts.

FIG. 2 illustrates a schematic diagram showing an ultrapure water supply apparatus according to some embodiments of the present inventive concepts.

FIG. 3 illustrates a schematic diagram showing a gas supply device according to some embodiments of the present inventive concepts.

FIG. 4 illustrates a schematic diagram partially showing a gas supply device according to some embodiments of the present inventive concepts.

FIG. 5 illustrates a schematic diagram partially showing a gas supply device according to some embodiments of the present inventive concepts.

FIG. 6 illustrates a cross-sectional view showing an example of a semiconductor processing chamber according to some embodiments of the present inventive concepts.

FIG. 7 illustrates a perspective view showing an example of a semiconductor processing chamber according to some embodiments of the present inventive concepts.

FIG. 8 illustrates a flow chart showing a substrate processing method according to some embodiments of the present inventive concepts.

FIGS. 9 to 14 illustrate schematic diagrams showing a substrate processing method according to the flow chart of FIG. 8.

FIG. 15 illustrates a schematic diagram showing a gas supply device according to some embodiments of the present inventive concepts.

FIG. 16 illustrates a schematic diagram partially showing a gas supply device according to some embodiments of the present inventive concepts.

FIG. 17 illustrates a schematic diagram partially showing a gas supply device according to some embodiments of the present inventive concepts.

### DETAILED DESCRIPTION

The following will now describe some embodiments of the present inventive concepts with reference to the accompanying drawings. Like reference numerals may indicate like components throughout the description.

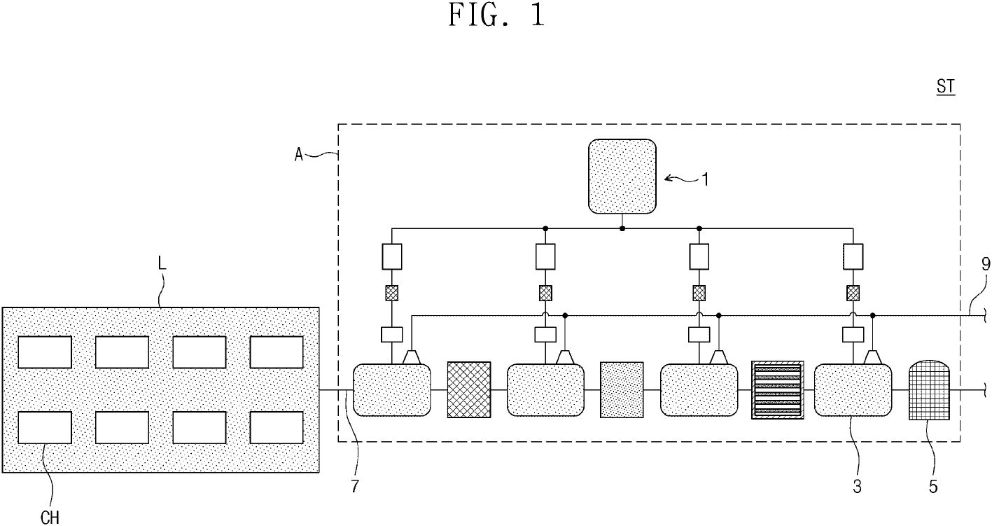

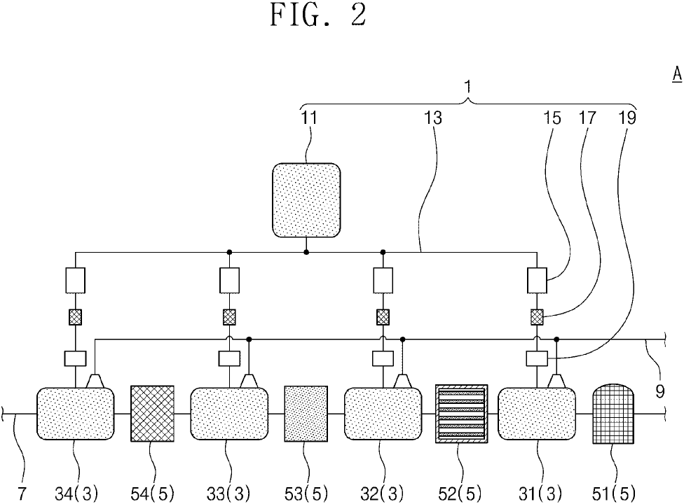

FIG. 1 illustrates a schematic diagram showing a substrate processing system according to some embodiments of the present inventive concepts. FIG. 2 illustrates a schematic diagram showing an ultrapure water supply apparatus according to some embodiments of the present inventive concepts.

Referring to FIG. 1, a substrate processing system ST may be provided. The substrate processing system ST may be a system to perform a process on a substrate. The substrate may include a wafer-type silicon (Si) substrate, but the present inventive concepts are not limited thereto. The substrate processing system ST may be configured to execute various processes on the substrate. For example, the substrate processing system ST may carry out a polishing process, a cleaning process, and/or an etching process on the substrate. It may be required that such processes use ultrapure water (UPW). The substrate processing system ST may include a semiconductor fabrication apparatus L and an ultrapure water supply apparatus A.

The semiconductor fabrication apparatus L may perform various processes on the substrate. The semiconductor fabrication apparatus L may include a plurality of substrate processing chambers CH. Each of the plurality of substrate processing chambers CH may be one of a substrate polishing apparatus, a substrate cleaning apparatus, and an etching apparatus. A detailed description thereof will be further discussed below.

The ultrapure water supply apparatus A may supply the semiconductor fabrication apparatus L with ultrapure water. For example, the ultrapure water supply apparatus A may produce ultrapure water from plain water, and may supply the produced ultrapure water to the semiconductor fabrication apparatus L. The ultrapure water supply apparatus A may include a filtering device or filter 5, an ultrapure water pipe 7, a tank 3, a gas supply device 1, and an exhaust pipe 9.

Referring to FIG. 2, the filtering device 5 may be provided in plural. The plurality of filtering devices 5 may be connected to each other in series. A fluid may be converted into ultrapure water while sequentially passing through the plurality of filtering devices 5. For example, ultrapure water may be produced by the plurality of filtering devices 5. The ultrapure water may be supplied to the semiconductor fabrication apparatus L. Each of the plurality of filtering devices 5 may include one of an activated carbon filter device, an ion exchange resin device, a reverse osmosis membrane device, and a hollow fiber membrane device.

For example, four filtering devices 5 may be provided. For example, as shown in FIG. 2, there may be provided a first filtering device 51, a second filtering device 52, a third filtering device 53, and a fourth filtering device 54.

The first filtering device 51 may receive and filter plain water. The plain water may be converted into de-ionized water (DIW) while passing through the first filtering device 51. A fluid that has passed through the first filtering device 51 may move along the ultrapure water pipe 7 to the second filtering device 52.

The second filtering device 52 may be connected to the first filtering device 51. The second filtering device 52 may be supplied with de-ionized water (DIW) from the first filtering device 51 and may then filter the de-ionized water. A fluid that has passed through the second filtering device 52 may move along the ultrapure water pipe 7 to the third filtering device 53.

The third filtering device 53 may be connected to the second filtering device 52. The third filtering device 53 may be supplied with de-ionized water (DIW) from the second filtering device 52 and may filter the de-ionized water. A fluid that has passed through the third filtering device 53 may move along the ultrapure water pipe 7 to the fourth filtering device 54.

The fourth filtering device 54 may be connected to the third filtering device 53. The fourth filtering device 54 may be supplied with de-ionized water (DIW) from the third filtering device 53 and may filter the de-ionized water. A fluid that has passed through the fourth filtering device 54 may move along the ultrapure water pipe 7 to the semiconductor fabrication apparatus L.

The present inventive concepts, however, are not limited thereto, and three or fewer filtering devices 5 may be provided. Alternatively, five or more filtering devices 5 may be provided. Unless otherwise stated below, a single filtering device 5 will be discussed.

The ultrapure water pipe 7 may connect to each other the filtering device 5, the tank 3, and the semiconductor fabrication apparatus L. A fluid may move along the ultrapure water pipe 7 and may be provided to the semiconductor fabrication apparatus L.

The tank 3 may be positioned between a plurality of filtering devices 5. A fluid may be stored for a certain time in the tank 3 between the plurality of filtering devices 5. For example, a fluid that has passed through one or more filtering devices 5 may be temporarily stored in the tank 3 before moving to a next filtering device 5. The tank 3 may be provided in plural. For example, as shown in FIG. 2, there may be provided a first tank 31, a second tank 32, a third tank 33, and a fourth tank 34.

The first tank 31 may be positioned between the first filtering device 51 and the second filtering device 52. A fluid that has passed through the first filtering device 51 may be temporarily stored in the first tank 31 and may then be transferred to the second filtering device 52.

The second tank 32 may be positioned between the second filtering device 52 and the third filtering device 53. A fluid that has passed through the second filtering device 52 may be temporarily stored in the second tank 32 and may then be transferred to the third filtering device 53.

The third tank 33 may be positioned between the third filtering device 53 and the fourth filtering device 54. A fluid that has passed through the third filtering device 53 may be temporarily stored in the third tank 33 and may then be transferred to the fourth filtering device 54.

The fourth tank 34 may be positioned between the fourth filtering device 54 and the semiconductor fabrication apparatus L. A fluid that has passed through the fourth filtering device 54 may be temporarily stored in the fourth tank 34 and may then be transferred to the semiconductor fabrication apparatus L.

The present inventive concepts, however, are not limited thereto, and three or fewer tanks 3 may be provided. Alternatively, five or more tanks 3 may be provided. Unless otherwise stated below, a single tank 3 will be discussed.

The gas supply device 1 may be connected to the tank 3. The gas supply device 1 may supply the tank 3 with a gas. For example, the gas supply device 1 may supply the tank 3 with an inert gas. For more detail, the gas supply device 1 may supply the tank 3 with a nitrogen (N₂) gas. The present inventive concepts, however, are not limited thereto, and the gas supply device 1 may supply the tank 3 with one or more of argon (Ar), neon (Ne), and helium (He). The gas supply device 1 may include a gas storage tank 11, a gas supply pipe 13, a bypass device 15, a filter 17, and a pressure controller 19.

The gas storage tank 11 may store and supply an inert gas. The gas storage tank 11 may be positioned on a location spaced apart from that of the semiconductor fabrication apparatus L.

The gas supply pipe 13 may connect the gas storage tank 11 and the tank 3 to each other. An inert gas may be supplied from the gas storage tank 11 along the gas supply pipe 13 to the tank 3.

The bypass device 15 may be coupled to the gas supply pipe 13. The bypass device 15 may bypass a portion of the gas supply pipe 13. The bypass device 15 will be further discussed in detail below.

The filter 17 may be positioned on the gas supply pipe 13. The filter 17 may filter foreign substances from an inert gas that flows in the gas supply pipe 13. The filter 17 may include various filtering structures. For example, the filter 17 may include a pre-filter, a HEPA filter, an ULPA filter. The present inventive concepts, however, are not limited thereto, and the filter 17 may include different kinds of filtering structures capable of filtering particles in a gas.

The pressure controller 19 may be coupled to the gas supply pipe 13. The pressure controller 19 may adjust a pressure of an inert gas that flows in the gas supply pipe 13. For example, the pressure controller 19 may control an inert gas flowing in the gas supply pipe 13 to maintain a pressure at a certain level. Therefore, the tank 3 may be provided with an inert gas at a constant pressure. The pressure controller 19 will be further discussed in detail below.

When the tank 3 is provided in plural, the gas supply device 1 may be connected to each of the plurality of tanks 3. In this case, each of the gas supply pipe 13, the bypass device 15, the filter 17, and the pressure controller 19 may be provided in plural. However, only one gas supply tank 11 may be provided. For example, a single gas storage tank 11 may provide an inert gas to each of the plurality of tanks 3.

The exhaust pipe 9 may be connected to the tank 3. An inert gas supplied through the gas supply device 1 to the tank 3 may be outwardly discharged through the exhaust pipe 9 from the tank 3. For example, when an internal pressure of the tank 3 is equal to or greater than a certain value, a portion of an inert gas within the tank 3 may be outwardly discharged along the exhaust pipe 9 from the tank 3. The exhaust pipe 9 may be spatially connected to an external space. For example, the exhaust pipe 9 may be connected to a space outside the substrate processing system ST. For example, the exhaust pipe 9 may be connected to an outer wall of a building so as to be exposed to an external space of the building. When the tank 3 is provided in plural, the exhaust pipe 9 may be connected to each of the plurality of tanks 3. An inert gas discharged from each of the plurality of tanks 3 may be discharged along one exhaust pipe 9 to an external space. A detailed description thereof will be further discussed below.

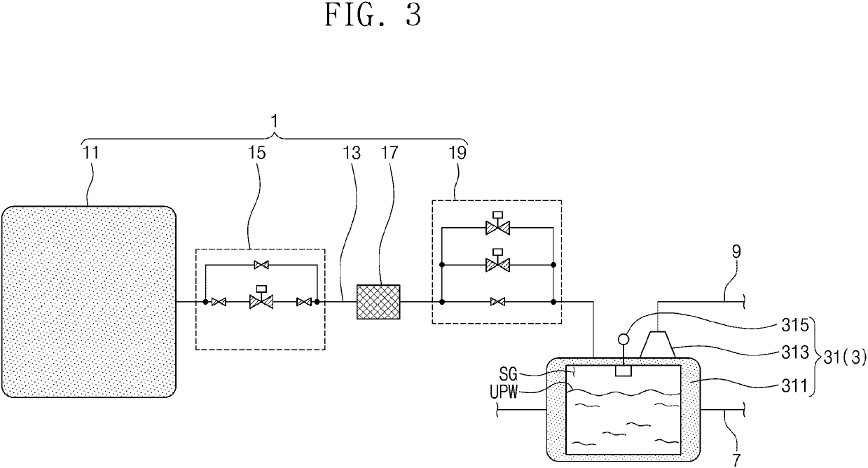

FIG. 3 illustrates a schematic diagram showing a gas supply device according to some embodiments of the present inventive concepts.

Referring to FIG. 3, the tank 3 may include a tank body 311, a breather valve 313, and a pressure measurement device 315.

The tank body 311 may provide a storage space SG. The tank body 311 may temporarily store ultrapure water UPW. For example, the ultrapure water UPW that has moved along the ultrapure water pipe 7 to the tank body 311 may be stored for a certain time in the storage space SG. Therefore, a portion of the storage space SG may be filled with the ultrapure water UPW. A remaining portion of the storage space SG may be filled with a gas. For example, the remaining portion of the storage space SG may be filled with an inert gas supplied from the gas supply device 1.

The breather valve 313 may be coupled to the tank body 311. For example, the breather valve 313 may be coupled to the tank body 311 so as to connect to the storage space SG. The breather valve 313 may be connected to an upper portion of the storage space SG. For example, the storage space SG may have a portion that is not occupied by the ultrapure water UPW, and the breather valve 313 may be connected to the unoccupied portion of the storage space SG. The breather valve 313 may be a valve that automatically operates due to a difference in pressure.

The breather valve 313 may outwardly discharge a gas in the storage space SG. Alternatively, the breather valve 313 may introduce an external gas into the storage space SG. The breather valve 313 may be configured to operate when a difference in pressure between the storage space SG and the outside is beyond a certain level. For example, when a relative pressure of the storage space SG is beyond a certain level, the breather valve 313 may operate. The relative pressure of the storage space SG may mean a pressure difference between the storage space SG and the outside. For example, a pressure of the storage space SG is greater than that of the outside by about 50 mmAq or higher, the breather valve 313 may be set such that a gas is discharged from the storage space SG. In this case, when an inert gas in the storage space SG has a relative pressure greater than about 50 mmAq, the breather valve 313 may allow an inert gas to escape from the storage space SG. Alternatively, when a pressure of the storage space SG is less than that of the outside by about 30 mmAq or higher, the breather valve 313 may be set such that an external gas is introduced into the storage space SG. In this case, when an inert gas in the storage space SG has a relative pressure less than about -30 mmAq, the breather valve 313 may allow an external gas to enter the storage space SG. The breather valve 313 may cause the storage space SG to maintain a pressure within a certain value range. The present inventive concepts, however, are not limited to a specific pressure range, and a detailed pressure range may be changed depending on design.

The breather valve 313 may be connected to the exhaust pipe 9. In this case, an outside of the tank 3 may indicate an inside of the exhaust pipe 9. The breather valve 313 may connect the storage space SG to the inside of the exhaust pipe 9. A gas discharged through the breather valve 313 from the storage space SG may move along the exhaust pipe 9.

Although not shown, the breather valve 313 may be provided in plural. For example, two or more breather valves 313 may be coupled in parallel to one tank body 311.

The pressure measurement device 315 may measure an internal pressure of the tank body 311. For example, the pressure measurement device 315 may measure a pressure of the storage space SG. At least a portion of the pressure measurement device 315 may be positioned in the storage space SG so as to measure the pressure of the storage space SG. The pressure measurement device 315 may include various configurations for measuring pressures of gases. For example, the pressure measurement device 315 may include a primary pressure gauge, such as manometer and/or barometer. Alternatively, the pressure measurement device 315 may include a secondary pressure gauge, such as Bourdon tube pressure gauge. The present inventive concepts, however, are not limited thereto, and the pressure measurement device 315 may include different kinds of pressure gauges capable of measuring a pressure of an inert gas in the storage space SG. The gas supply device 1 may be controlled based on information about a measured pressure of an inert gas in the storage space SG. A detailed description thereof will be further discussed below.

FIG. 4 illustrates a schematic diagram partially showing a gas supply device according to some embodiments of the present inventive concepts.

Referring to FIG. 4, the bypass device 15 may include a bypass pipe 151, a bypass valve 155, a main valve 153, and a shutoff valve 157.

The bypass pipe 151 may be coupled to the gas supply pipe 13. The bypass pipe 151 may bypass a portion of the gas supply pipe 13. For example, at some region, the bypass pipe 151 and a portion of the gas supply pipe 13 may be connected to each other in parallel.

The bypass valve 155 may be positioned on the bypass pipe 151. The bypass valve 155 may open and close the bypass pipe 151. The bypass valve 155 may include a manual valve, but the present inventive concepts are not limited thereto.

The main valve 153 may be coupled onto the gas supply pipe 13. The main valve 153 may open and close the gas supply pipe 13. The main valve 153 may be disposed in parallel to the bypass valve 155. The main valve 153 may include an automatic valve (AV). For example, the main valve 153 may be automatically opened and closed. The present inventive concepts, however, are not limited thereto.

The shutoff valve 157 may be coupled to the gas supply pipe 13 between the bypass pipe 151 and the main valve 153. The shutoff valve 157 may be provided in plural. For example, as shown in FIG. 4, there may be provided a first shutoff valve 1571 and a second shutoff valve 1573. The shutoff valve 157 may be opened or closed to allow or prevent the flow of a gas to the main valve 153.

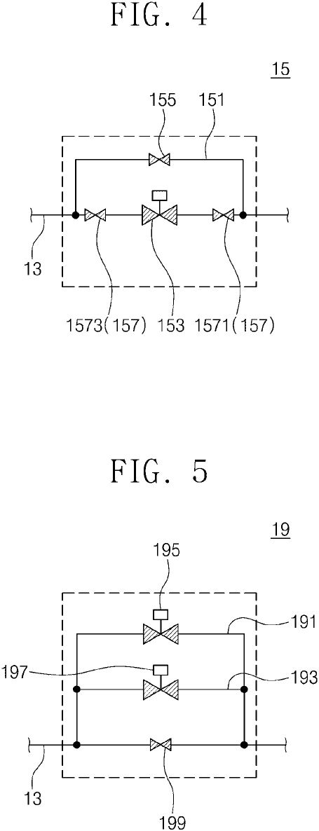

FIG. 5 illustrates a schematic diagram partially showing a gas supply device according to some embodiments of the present inventive concepts.

Referring to FIG. 5, the pressure controller 19 may adjust a pressure of an inert gas that flows in the gas supply pipe 13. For example, the pressure controller 19 may control an inert gas flowing in the gas supply pipe 13 to maintain a pressure at a certain level. The pressure controller 19 may include a first pressure control pipe 191, a second pressure control pipe 193, a first pressure control valve 195, a second pressure control valve 197, and a reserved valve 199.

The first pressure control pipe 191 may be coupled to the gas supply pipe 13. The first pressure control pipe 191 may bypass a portion of the gas supply pipe 13. For example, at some region, the first pressure control pipe 191 and a portion of the gas supply pipe 13 may be connected to each other in parallel.

The second pressure control pipe 193 may be coupled to the gas supply pipe 13. The second pressure control pipe 193 may bypass a portion of the gas supply pipe 13. For example, at some region, the first pressure control pipe 191, the second pressure control pipe 193, and a portion of the gas supply pipe 13 may be connected to each other in parallel.

The first pressure control valve 195 may be positioned on the first pressure control pipe 191. The first pressure control valve 195 may open and close the first pressure control pipe 191. The first pressure control valve 195 may include a gas seal valve (GSV) and/or level control valve (LCV). The first pressure control valve 195 may control an inert gas flowing in the first pressure control pipe 191 to have a pressure at a certain level. For example, the first pressure control valve 195 may control an inert gas flowing in the first pressure control pipe 191 to have a relative pressure of about 30 mmAq. The present inventive concepts, however, are not limited thereto, and a pressure value controlled by the first pressure control valve 195 may be changed based on a detailed design.

The second pressure control valve 197 may be positioned on the second pressure control pipe 193. The second pressure control valve 197 may open and close the second pressure control pipe 193. The second pressure control valve 197 may be substantially the same as or similar to the first pressure control valve 195.

The reserved valve 199 may be positioned on the gas supply pipe 13. The reserved valve 199 may open and close the gas supply pipe 13. The reserved valve 199 may include a manual valve, but the present inventive concepts are not limited thereto.

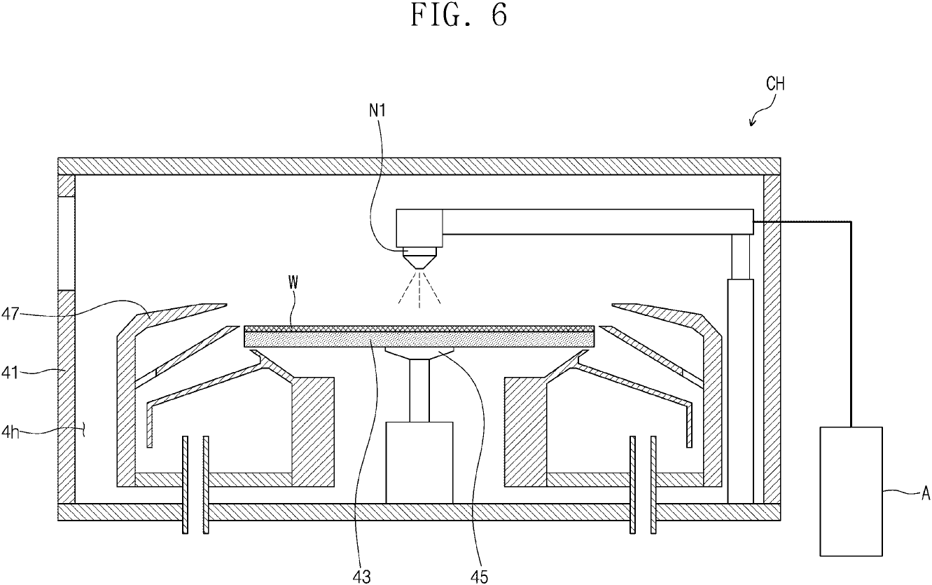

FIG. 6 illustrates a cross-sectional view showing an example of a semiconductor processing chamber according to some embodiments of the present inventive concepts.

Referring to FIG. 6, the semiconductor processing chamber CH may include a substrate cleaning apparatus. In this case, the substrate processing chamber CH may include a cleaning chamber 41, a cleaning stage 43, a rotational driving mechanism 45, a cleaning nozzle N1, and a cleaning bowl 47.

The cleaning chamber 41 may provide a cleaning space 4h. A cleaning process may be performed on a substrate W in the cleaning chamber 41.

The cleaning stage 43 may be positioned in the cleaning chamber 41. The cleaning stage 43 may support the substrate W.

The rotational driving mechanism 45 may rotate the cleaning stage 43. Therefore, the substrate W may rotate on the cleaning stage 43 that rotates.

The cleaning nozzle N1 may be above and spaced apart from the cleaning stage 43. The cleaning nozzle N1 may be connected to the ultrapure water supply apparatus A. Ultrapure water may be supplied from the ultrapure water supply apparatus A to the cleaning nozzle N1, thereby being sprayed onto the substrate W. The substrate W on the cleaning stage 43 may be cleaned by the ultrapure water sprayed from the cleaning nozzle N1. In this case, the substrate W may rotate driven by the cleaning stage 43. The ultrapure water in contact with a top surface of the substrate W may be pushed outwardly.

The cleaning bowl 47 may surround the cleaning stage 43. The cleaning bowl 47 may collect the ultrapure water that is outwardly pushed from the top surface of the substrate W.

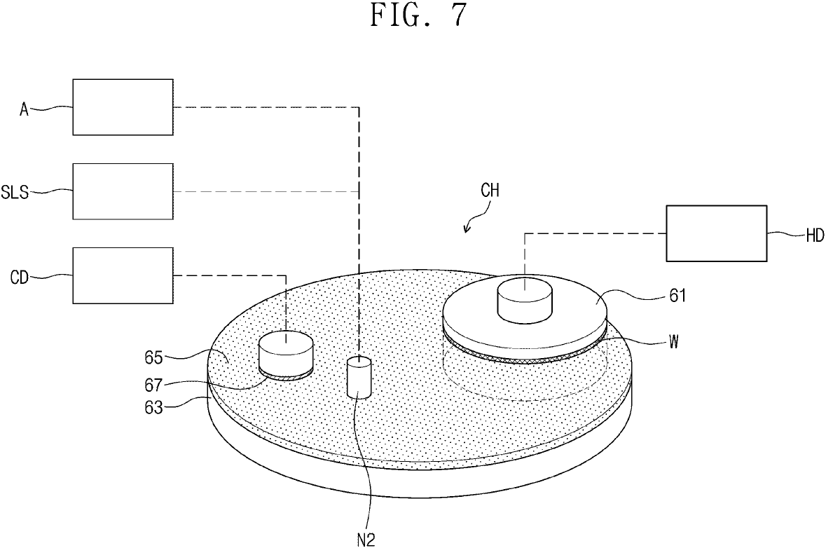

FIG. 7 illustrates a perspective view showing an example of a semiconductor processing chamber according to some embodiments of the present inventive concepts.

Referring to FIG. 7, the semiconductor processing chamber CH may include a substrate polishing apparatus. In this case, the substrate processing chamber CH may include a polishing head 61, a polishing stage 63, a polishing pad 65, a conditioning disk 67, a head driving part or head driver HD, a conditioning driving part or conditioning driver CD, a slurry supply part or slurry supplier SLS, and a polishing nozzle N2.

The polishing head 61 may support the substrate W. The polishing pad 65 may polish the substrate W supported by the polishing head 61. The polishing stage 63 may rotate the polishing pad 65. The polishing pad 65 may polish one surface of the substrate W while being in contact with the substrate W. The conditioning disk 67 may improve a condition of a top surface of the polishing pad 65. For example, the conditioning disk 67 may polish the top surface of the polishing pad 65. The head driving part HD may rotate and/or translate the polishing head 61. The conditioning driving part CD may drive the conditioning disk 67 to move. The slurry supply part SLS may supply the polishing nozzle N2 with slurry. The polishing nozzle N2 may be connected to the slurry supply part SLS and the ultrapure water supply apparatus A. The ultrapure water supply apparatus A may supply the polishing nozzle N2 with ultrapure water. The polishing nozzle N2 may mix the slurry supplied from the slurry supply part SLS with the ultrapure water supplied from the ultrapure water supply apparatus A, and may spray the mixture onto the polishing pad 65.

FIGS. 6 or 7 shows that the substrate processing chamber CH is a substrate cleaning apparatus or a substrate polishing apparatus, but the present inventive concepts are not limited thereto. For example, the substrate processing chamber CH may include any other apparatus in which ultrapure water is used to perform a treatment process on a substrate.

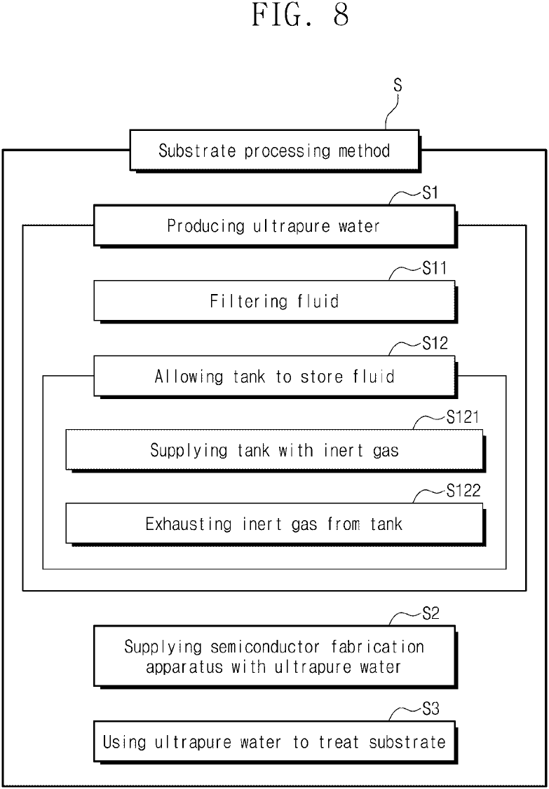

FIG. 8 illustrates a flow chart showing a substrate processing method according to some embodiments of the present inventive concepts.

Referring to FIG. 8, a substrate processing method S may be provided. The substrate processing method S may include a step S1 of producing ultrapure water, a step S2 of providing a semiconductor fabrication apparatus with the ultrapure water, and a step S3 of using the ultrapure water to treat a substrate.

The ultrapure water production step S1 may include a step S11 of filtering a fluid and a step S12 of allowing a tank to store the fluid.

The fluid storage step S12 may include a step S121 of providing the tank with an inert gas and a step S122 of exhausting the inert gas from the tank.

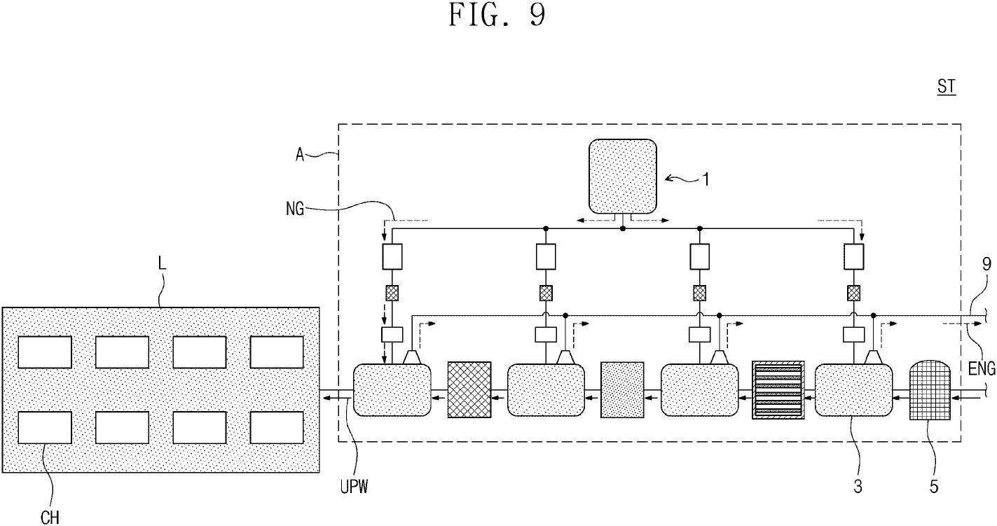

The substrate processing method S will be discussed in detail below with reference to FIGS. 9 to 14.

FIGS. 9 to 14 illustrate schematic diagrams showing a substrate processing method according to the flow chart of FIG. 8.

Referring to FIGS. 2, 8, and 9, the fluid filtering step S11 may include allowing the fluid to become ultrapure water UPW while passing through a plurality of filtering devices 5. For example, a fluid introduced into the first filtering device 51 may sequentially pass through the first tank 31, the second filtering device 52, the second tank 32, the third filtering device 53, the third tank 33, and the fourth filtering device 54, thereby becoming the ultrapure water UPW. In this procedure, the fluid may be temporarily stored in the tank 3.

Referring to FIGS. 8 and 10, the inert gas supply step S121 may be performed by the gas supply device 1. For example, an inert gas NG supplied from the gas storage tank 11 may pass along the gas supply pipe 13 and sequentially pass through the bypass device 15, the filter 17, and the pressure controller 19, thereby being supplied to the storage space SG of the tank 3. In this step, the ultrapure water UPW may be present in the storage space SG. In the storage space SG, the inert gas NG may be positioned on the ultrapure water UPW.

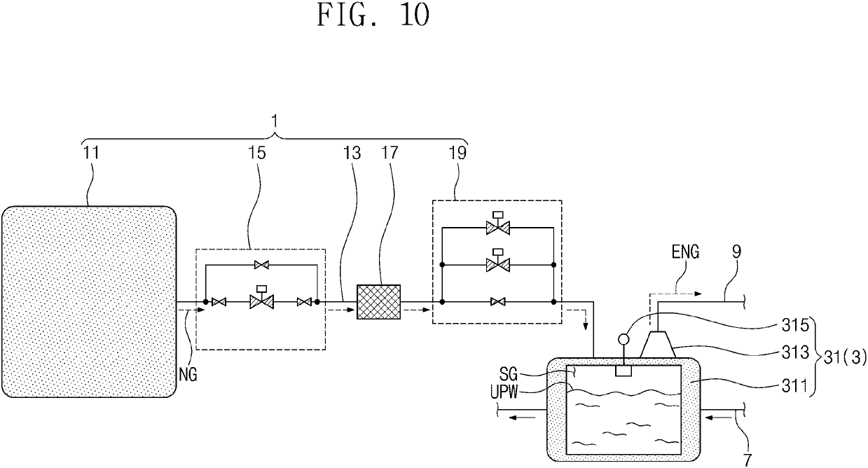

Referring to FIG. 11, when the main valve 153 is opened, the inert gas NG may pass through the main valve 153 and move along the gas supply pipe 13. This state may be called a normal operating state.

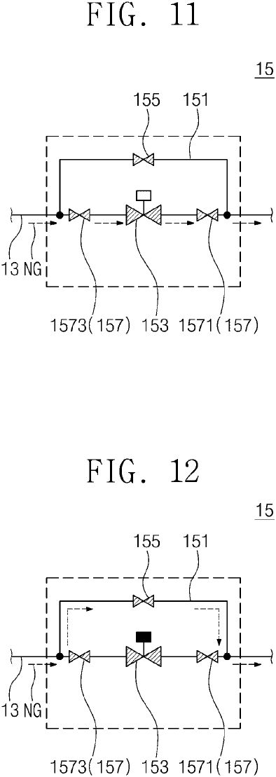

Referring to FIG. 12, when the main valve 153 is in trouble (e.g., malfunctioning), the main valve 153 and/or the shutoff valve 157 may be closed. Simultaneously, the bypass valve 155 may be opened. Therefore, the inert gas NG may move through the bypass pipe 151 and the bypass valve 155. This state may be called an abnormal operating state or a bypass operating state.

Based on a state of the main valve 153, one of the main valve 153 and the bypass valve 155 may be opened, and the other of the main valve 153 and the bypass valve 155 may be closed. In this case, even when the main valve 153 is in trouble, an inert gas may be continuously provided through the bypass pipe 151 and the bypass valve 155. Therefore, the supply of the inert gas may not be stopped even in the abnormal operating state. During the supply of the inert gas that passes through the bypass pipe 151 and the bypass valve 155, the main valve 153 may be repaired or replaced.

Referring to FIG. 13, when the second pressure control valve 197 is opened, the inert gas NG may pass through the second pressure control valve 197 and move along the second pressure control pipe 193. This state may be called a first normal operating state. In the first normal operating state, the first pressure control valve 195 and the reserved valve 199 may be closed.

In the first normal operating state, the second pressure control valve 197 may control the inert gas NG in the second pressure control pipe 193 to have a pressure at a certain level. For example, the second pressure control valve 197 may control the inert gas NG in the second pressure control pipe 193 to have a relative pressure of about 30 mmAq. Therefore, the inert gas NG may be supplied at a constant pressure.

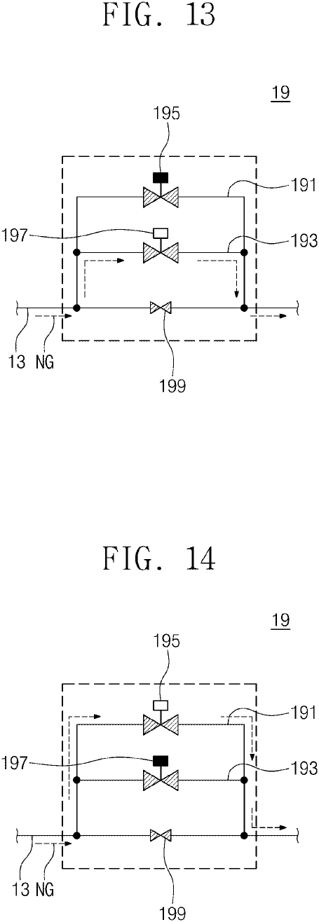

Referring to FIG. 14, when the first pressure control valve 195 is opened, the inert gas NG may pass through the first pressure control valve 195 and move along the first pressure control pipe 191. This state may be called a second normal operating state. In the second normal operating state, the second pressure control valve 197 and the reserved valve 199 may be closed.

In the second normal operating state, the first pressure control valve 195 may control the inert gas NG in the first pressure control pipe 191 to have a pressure at a certain level. For example, the first pressure control valve 195 may control the inert gas NG in the first pressure control pipe 191 to have a relative pressure of about 30 mmAq. Therefore, the inert gas NG may be supplied at a constant pressure.

The first normal operating state may be executed when the first pressure control valve 195 is in trouble (e.g., malfunctioning). In addition, the second normal operating state may be executed when the second pressure control valve 197 is in trouble (e.g., malfunctioning). Therefore, even though abnormality occurs in one of the first and second pressure control valves 195 and 197, the other of the first and second pressure control valves 195 and 197 may be used to stably supply an inert gas. Moreover, when abnormality occurs in both of the first and second pressure control valves 195 and 197, a process may be continuously performed by closing each of the first and second pressure control valves 195 and 197 and by opening the reserved valve 199.

Referring back to FIG. 10, the pressure measurement device 315 may measure a pressure of the storage space SG. The opening degree of one or both of the first and second pressure control valves (see 195 and 197 in FIG. 13) may be adjusted based on the pressure of the storage space SG measured by the pressure measurement device 315. For example, when a relative pressure of the storage space SG is less than a certain value, one or both of the first and second pressure control valves 195 and 197 may be more opened. Therefore, the relative pressure of the storage space SG may be recovered or increased to a certain level. For example, when a relative pressure of the storage space SG measured by the pressure measurement device 315 is less than about -30 mmAq, one or both of the first and second pressure control valves 195 and 197 may be more opened. Alternatively, when a relative pressure of the storage space SG is greater than a certain value, one or both of the first and second pressure control valves 195 and 197 may be slightly closed. For example, a pressure of the storage space SG may be ascertained in real time to control the first and second pressure control valves 195 and 197. Accordingly, the storage space SG may maintain a pressure at a constant level.

Referring back to FIGS. 8 and 10, the inert gas exhaust step S122 may be performed by the breather valve 313. For example, when a relative pressure of the storage space SG is greater than a certain value, the breather valve 313 may allow an inert gas ENG of the storage space SG to outwardly escape through the exhaust pipe 9 from the tank 3. For example, when a relative pressure of the storage space SG is greater than about 50 mmAq, the breather valve 313 may discharge the inert gas ENG. In contrast, when a relative pressure of the storage space SG is less than a certain value, the breather valve 313 may allow an external gas to enter the storage space SG. For example, when a relative pressure of the storage space SG is less than about -30 mmAq, the breather valve 313 may allow an external gas to enter the storage space SG. Accordingly, the storage space SG may always maintain a pressure at a constant level.

Referring back to FIGS. 8 and 9, the ultrapure water supply step S2 may include providing the semiconductor fabrication apparatus L with ultrapure water UPW produced in the ultrapure water supply apparatus A.

Referring back to FIGS. 6, 7, and 8, the substrate treatment step S3 may include allowing the semiconductor processing chamber CH to perform a process in which ultrapure water is used. For example, when the semiconductor processing chamber CH includes a substrate cleaning apparatus as shown in FIG. 6, ultrapure water may clean the substrate W on the cleaning stage 43. For example, ultrapure water sprayed from the cleaning nozzle N1 may clean one surface of the substrate W that rotates. Alternatively, when the semiconductor processing chamber CH includes a substrate polishing apparatus as shown in FIG. 7, ultrapure water and slurry that is supplied from the slurry supply part SLS may polish the substrate W. For example, slurry mixed with ultrapure water may be sprayed from the polishing nozzle N2 onto the polishing pad 65 that rotates to polish one surface of the substrate W.

According to an ultrapure water supply apparatus, a substrate processing system including the same, and a substrate processing method using the same in accordance with some embodiments of the present inventive concepts, an inert gas may be supplied to a tank for temporarily storing ultrapure water. Therefore, the ultrapure water in the tank may be prevented from contamination due to contact with an external gas. For example, the ultrapure water may be protected to maintain quality at a constant level. Accordingly, a substrate process may increase in yield.

According to an ultrapure water supply apparatus, a substrate processing system including the same, and a substrate processing method using the same in accordance with some embodiments of the present inventive concepts, when an internal pressure of the tank is less than a certain level, a breather valve may be used to allow an external gas to enter and exit the tank. Thus, the tank may maintain the internal pressure at a constant level. Accordingly, the tank may be prevented from damage caused by difference in pressure. For example, although a flow rate of ultrapure water and/or of inert gas is abruptly changed, it may be possible to flexibly cope with the situation and to protect the tank.

According to an ultrapure water supply apparatus, a substrate processing system including the same, and a substrate processing method using the same in accordance with some embodiments of the present inventive concepts, a pressure control valve may be controlled based on the internal pressure of the tank. For example, a pressure measurement device may be used to measure a pressure of a storage space in real time. Thus, the tank may maintain the internal pressure at a constant level.

According to an ultrapure water supply apparatus, a substrate processing system including the same, and a substrate processing method using the same in accordance with some embodiments of the present inventive concepts, a bypass device and/or a plurality of pressure control valves may be used to stably supply the inert gas. For example, even when one or more valves are in trouble (e.g., malfunctioning), the remaining valves may be used to continuously supply the inert gas. Accordingly, the tank may be prevented from damage or contamination caused by interruption of supply of the inert gas.

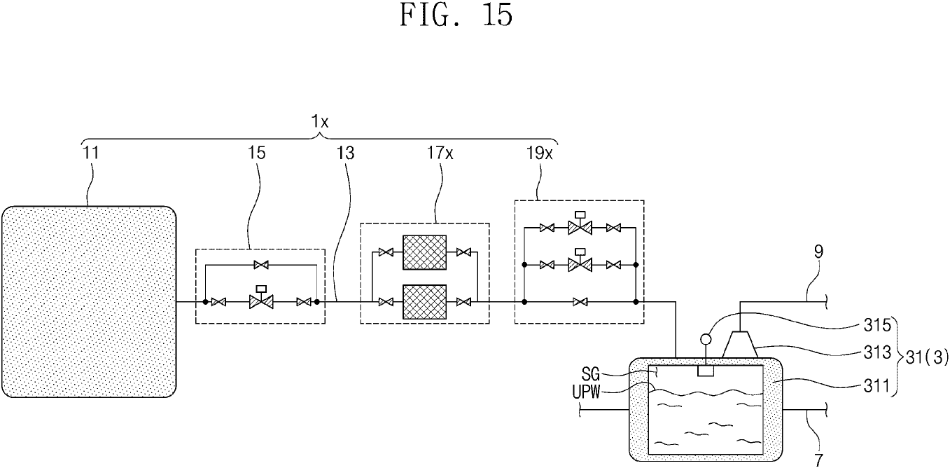

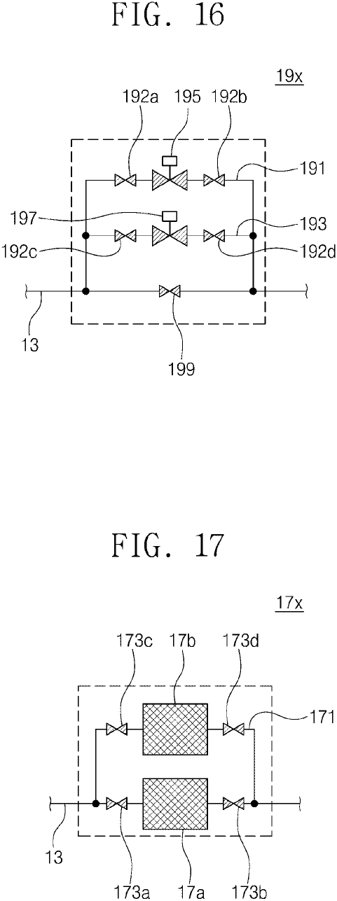

FIG. 15 illustrates a schematic diagram showing a gas supply device according to some embodiments of the present inventive concepts. FIG. 16 illustrates a schematic diagram partially showing a gas supply device according to some embodiments of the present inventive concepts. FIG. 17 illustrates a schematic diagram partially showing a gas supply device according to some embodiments of the present inventive concepts.

The following may omit a description of contents substantially the same as or similar to that discussed with reference to FIGS. 1 to 14.

Referring to FIGS. 15 and 16, a gas supply device 1x may include a pressure controller 19x. Unlike that discussed with reference to FIG. 5, the pressure controller 19x of FIG. 16 may include a plurality of shutoff valves 192a, 192b, 192c, and 192d. For example, a first shutoff valve 192a and a second shutoff valve 192b may be respectively disposed on a front end and a rear end of the first pressure control valve 195 (or upstream and downstream the first pressure control valve 195). In addition, a third shutoff valve 192c and a fourth shutoff valve 192d may be respectively disposed on a front end and a rear end of the second pressure control valve 197 (or upstream and downstream the second pressure control valve 197). Each of the plurality of shutoff valves 192a, 192b, 192c, and 192d may include a manual valve, but the present inventive concepts are not limited thereto.

According to an ultrapure water supply apparatus, a substrate processing system including the same, and a substrate processing method using the same in accordance with some embodiments of the present inventive concepts, when a pressure control valve is in trouble (e.g., malfunctioning), a shutoff valve adjacent to the troubled pressure control valve may be closed to prevent a flow of fluid to the troubled pressure control valve. Simultaneously, another pressure control valve may be opened to allow the fluid to flow to that pressure control valve. During this procedure, the troubled pressure control valve may be repaired or replaced. This arrangement may allow an inert gas to be continuously supplied even when one or more pressure control valves are in trouble. Accordingly, ultrapure water in a tank may be continuously prevented from contamination.

Referring to FIGS. 15 and 17, the gas supply device 1x may include a parallel filter device 17x. Unlike that discussed with reference to FIG. 3, the parallel filter device 17x of FIG. 17 may include a plurality of filters 17a and 17b. For example, the parallel filter device 17x may include a first filter 17a, a first filter shutoff valve 173a, a second filter shutoff valve 173b, a bypass filter pipe 171, a second filter 17b, a third filter shutoff valve 173c, and a fourth filter shutoff valve 173d. The first filter 17a may be positioned on the gas supply pipe 13. The first filter shutoff valve 173a and the second filter shutoff valve 173b may be respectively disposed on a front end and a rear end of the first filter 17a (or upstream and downstream the first filter 17a). The bypass filter pipe 171 may be connected to the gas supply pipe 13 so as to bypass the first filter 17a. The second filter 17b may be positioned on the bypass filter pipe 171. The third filter shutoff valve 173c and the fourth filter shutoff valve 173d may be respectively disposed on a front end and a rear end of the second filter 17b (or upstream and downstream the second filter 17b).

According to an ultrapure water supply apparatus, a substrate processing system including the same, and a substrate processing method using the same in accordance with some embodiments of the present inventive concepts, a plurality of filters may be provided in parallel. Therefore, when a filter is in trouble (e.g., malfunctioning), a filter shutoff valve adjacent to the troubled filter may be closed to prevent a flow of fluid to the troubled filter. Simultaneously, a filter shutoff valve adjacent to another filter may be opened to allow the fluid to flow to that filter. During this procedure, the troubled filter may be repaired or replaced. This arrangement may allow an inert gas to be continuously filtered even when one or more filters are in trouble. Accordingly, ultrapure water in a tank may be continuously prevented from contamination.

According to an ultrapure water supply apparatus, a substrate processing system including the same, and a substrate processing method using the same of the present inventive concepts, it may be possible to employ an inert gas to protect ultrapure water.

According to an ultrapure water supply apparatus, a substrate processing system including the same, and a substrate processing method using the same of the present inventive concepts, it may be possible to protect a tank that stores the ultrapure water.

According to an ultrapure water supply apparatus, a substrate processing system including the same, and a substrate processing method using the same of the present inventive concepts, it may be possible to continuously supply the inert gas.

Effects of the present inventive concepts are not limited to those mentioned above, and other effects which have not been mentioned above will be clearly understood to those skilled in the art from the description herein.

Although the present inventive concepts have been described in connection with the embodiments of the present inventive concepts illustrated in the accompanying drawings, it will be understood to those skilled in the art that various changes and modifications may be made without departing from the scope of the present inventive concepts. It therefore will be understood that the embodiments described above are just illustrative but not limitative in all aspects.

What is claimed is:

1. An ultrapure water supply apparatus, comprising:
a first filtering device;
a second filtering device connected to the first filtering device;
a first tank between the first filtering device and the second filtering device;
a third filtering device connected to the second filtering device;
a second tank between the second filtering device and the third filtering device;
a fourth filtering device connected to the third filtering device;
a third tank between the third filtering device and the fourth filtering device; and
a gas supply device connected to each of the first tank, the second tank, and the third tank, the gas supply device configured to supply an inert gas,
wherein each of the first, second, and third tanks includes:
a tank body; and
a breather valve coupled to the tank body and connected to a storage space in the tank body, and
wherein each of the first, second, third, and fourth filtering devices includes at least one selected from an activated carbon filter device, an ion exchange resin device, a reverse osmosis membrane device, and a hollow fiber membrane device.

2. The ultrapure water supply apparatus of claim 1, wherein the gas supply device includes:
a gas storage tank that stores the inert gas;
a gas supply pipe that connects the gas storage tank and the tank body;
a filter on the gas supply pipe; and
a pressure control valve on the gas supply pipe.

3. The ultrapure water supply apparatus of claim 2, wherein
the pressure control valve comprises a plurality of pressure control valves, and
the plurality of pressure control valves are disposed in parallel to each other.

4. The ultrapure water supply apparatus of claim 2, wherein the gas supply device further includes a bypass device on the gas supply pipe,
wherein the bypass device includes:
a bypass pipe that bypasses the gas supply pipe;
a bypass valve on the bypass pipe; and
a main valve on the gas supply pipe so as to be disposed in parallel to the bypass valve.

5. The ultrapure water supply apparatus of claim 2, wherein
the gas supply pipe comprises a plurality of gas supply pipes, and
each of the plurality of gas supply pipes is connected to a corresponding one of the first tank, the second tank, and the third tank.

6. The ultrapure water supply apparatus of claim 1, wherein each of the first, second, and third tanks further includes a pressure measurement device configured to measure a pressure of the storage space in the tank body.

7. The ultrapure water supply apparatus of claim 1, wherein each of the first, second, and third tanks further includes an exhaust pipe connected to the breather valve.

8. A substrate processing system, comprising:
a semiconductor fabrication apparatus; and
an ultrapure water supply apparatus configured to produce ultrapure water and supply the semiconductor fabrication apparatus with the ultrapure water,
wherein the ultrapure water supply apparatus includes:
a first filtering device;
a second filtering device connected to the first filtering device;
a first tank between the first filtering device and the second filtering device; and
a gas supply device configured to supply the first tank with an inert gas,
wherein the first tank includes:
a tank body; and
a breather valve coupled to the tank body and connected to a storage space in the tank body, and
wherein the gas supply device includes:
a gas storage tank that stores the inert gas;
a gas supply pipe that connects the gas storage tank and the tank body;
a filter on the gas supply pipe; and
a pressure control valve on the gas supply pipe.

9. The substrate processing system of claim 8, wherein the gas supply device further includes a bypass device on the gas supply pipe,
wherein the bypass device includes:
a bypass pipe that bypasses the gas supply pipe;
a bypass valve on the bypass pipe; and
a main valve on the gas supply pipe so as to be disposed in parallel to the bypass valve.

10. The substrate processing system of claim 8, wherein the first tank further includes a pressure measurement device configured to measure a pressure of the storage space in the tank body.

11. The substrate processing system of claim 8, wherein
when a relative pressure of the inert gas in the storage space is less than about 30 mmAq, the breather valve is configured to allow an external gas to enter the tank body, and
when a relative pressure of the inert gas in the storage space is greater than about 50 mmAq, the breather valve is configured to allow the inert gas in the tank body to escape from the tank body.

12. The substrate processing system of claim 8, wherein the first tank further includes an exhaust pipe connected to the breather valve,
wherein the exhaust pipe is connected to an outside of the substrate processing system.

13. The substrate processing system of claim 8, wherein the semiconductor fabrication apparatus includes at least one selected from a substrate polishing apparatus, a substrate cleaning apparatus, and an etching apparatus.

14. A substrate processing method, comprising:
using an ultrapure water supply apparatus to produce ultrapure water;
supplying the ultrapure water from the ultrapure water supply apparatus to a semiconductor fabrication apparatus; and
using the ultrapure water to treat a substrate in the semiconductor fabrication apparatus,
wherein producing the ultrapure water includes:
passing a fluid sequentially through a plurality of filtering devices to filter the fluid; and
storing the fluid in a tank between the plurality of filtering devices,
wherein storing the fluid in the tank includes:
supplying an inert gas to the tank in which the fluid is stored; and
discharging the inert gas from the tank.

15. The substrate processing method of claim 14, wherein the tank includes:
a tank body; and
a breather valve coupled to the tank body and connected to a storage space in the tank body, and
wherein discharging the inert gas from the tank is performed by the breather valve.

16. The substrate processing method of claim 15, wherein the breather valve is configured
to allow an external gas to enter the tank body when a relative pressure of the inert gas in the storage space is less than about -30 mmAq, and
to allow the inert gas in the tank body to escape from the tank body when a relative pressure of the inert gas in the storage space is greater than about 50 mmAq.

17. The substrate processing method of claim 15, wherein the tank is connected to a gas supply device that is configured to supply the tank with an inert gas,
wherein the gas supply device includes:
a gas storage tank that stores the inert gas;
a gas supply pipe that connects the gas storage tank and the tank body;
a filter on the gas supply pipe; and
a pressure control valve on the gas supply pipe,
wherein supplying the inert gas to the tank is performed by the gas supply device.

18. The substrate processing method of claim 17, wherein the pressure control valve is configured to allow the inert gas in the gas supply pipe to have a relative pressure of about 30 mmAq.

19. The substrate processing method of claim 17, wherein the tank further includes a pressure measurement device configured to measure a pressure of the storage space in the tank body,
wherein supplying the inert gas to the tank includes increasingly opening the pressure control valve when a relative pressure of the inert gas in the storage space is less than about -30 mmAq.

20. The substrate processing method of claim 17, wherein the gas supply device further includes a bypass device on the gas supply pipe,
wherein the bypass device includes:
a bypass pipe that bypasses the gas supply pipe;
a bypass valve on the bypass pipe; and
a main valve on the gas supply pipe so as to be disposed in parallel to the bypass valve,
wherein supplying the inert gas to the tank includes, based on a state of the main valve, opening only one of the main valve and the bypass valve and closing the other one of the main valve and the bypass valve.
